(19) United States
(12) Patent Application Publication
(10) Pub. No.: US 2009/0166731 A1
(43) Pub. Date: Jul. 2, 2009

(54) VERTICAL-TYPE FIELD-EFFECT TRANSISTOR AND MANUFACTURING METHOD THEREOF

(75) Inventor: Michiaki MARUOKA, Shiga (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/329,069

(22) Filed: Dec. 5, 2008

(30) Foreign Application Priority Data
Dec. 26, 2007 (JP) 2007-334944

(51) Int. Cl. H01L 29/78; H01L 21/336

(52) U.S. Cl. 257/330; 438/270; 257/E29.262; 257/E21.41

(57) ABSTRACT

A vertical-type FET includes: a semiconductor layer having a plurality of trenches; a gate electrode partially embedded in the trenches; and a base region and a source region that are formed in the semiconductor layer between adjacent trenches. The gate electrode includes: a plurality of first gate structures respectively formed in the plurality of trenches, wherein each first gate structure has a protruding portion protruding from the trench and an embedded portion embedded in the trench; and a second gate structure formed to connect between the protruding portions of adjacent first gate structures. The embedded portion is formed on a side wall of the trench through a first insulating film. The second gate structure is formed on the source region through a second insulating film thicker than the first insulating film.

### INCORPORATION BY REFERENCE

This application is based upon and claims the benefit of priority from Japanese patent application No. 2007-334944, filed on Dec. 26, 2007, the disclosure of which is incorporated herein in its entirely by reference.

### BACKGROUND OF THE INVENTION

1. Field of the Invention

The present invention relates to a field-effect transistor. In particular, the present invention relates to a field-effect transistor having a gate electrode embedded in a trench and a manufacturing method thereof.

2. Description of Related Art

In a technical filed of a power MOSFET, to reduce an ON-resistance Ron is one of most important issues. For reducing the ON-resistance Ron, it is effective to miniaturize an element. A vertical-type MOSFET (Metal Oxide Semiconductor Field-Effect Transistor) is known as an excellent element from a viewpoint of the miniaturization. In particular, a vertical-type MOSFET having a gate electrode embedded in a trench is advantageous for reducing a cell area. The following techniques have been proposed for the purpose of further reducing the ON-resistance Ron of the vertical-type MOSFET.

Japanese Laid-Open Patent Application JP-H10-93086 (hereinafter referred to as “Patent Document 1”) discloses a vertical-type MOSFET intended to reduce the ON-resistance Ron. The vertical-type MOSFET has stripe-shape trenches that are selectively formed on a semiconductor substrate. An insulating film is so formed as to cover inner wall surfaces of the trenches, and gate electrode material layers are embedded in respective trenches. An impurity layer constituting a part of the transistor is provided in contact with the insulating film on the periphery of the trench. Moreover, in order to electrically connect the gate electrode material layers with each other, the vertical-type MOSFET has a gate metal interconnection that is so provided as to extend in a direction intersecting with the stripe-like trenches. The gate metal interconnection is formed in an upper layer as compared with the gate electrode material layers. The above-mentioned trenches, insulating film, gate electrode material layers and impurity layer are formed to cross below the gate metal interconnection. As a result, an effective channel width is increased and hence the ON-resistance Ron is reduced.

Japanese Laid-Open Patent Application JP-2003-318396 (hereinafter referred to as “Patent Document 2”) discloses a vertical-type MOSFET intended to reduce a cell size. According to the vertical-type MOSFET, a unit cell is constructed in a region surrounded by trench-type gates provided in a semiconductor substrate. A base layer and a source layer are formed in the unit cell, and a trench-type contact is so formed at a center of the unit cell as to reach the source layer and the base layer. A source electrode connected with the contact is formed on a surface of the substrate, and a drain electrode is formed on a back surface of the substrate. Moreover, the contact is so formed as to reach a depth which is different from a peak depth of impurity concentration in the base layer, and a base contact layer is formed on the bottom of the contact. In this manner, the cell size can be reduced without increasing a threshold voltage and a source resistance.

A parameter that relates to characteristics of the vertical-type MOSFET is not limited to the above-mentioned ON-resistance Ron. Parameters such as a gate resistance Rg, a gate charge Qg and a gate-to-drain charge Qgd contribute to the characteristics of the vertical-type MOSFET.

Japanese Laid-Open Patent Application JP-2004-31385 (hereinafter referred to as “Patent Document 3”) discloses a vertical-type MOSFET intended to reduce the gate resistance Rg. The vertical-type MOSFET has a gate electrode of a trench structure that is formed in a stripe shape in a semiconductor substrate in an actual operation region. Furthermore, a grid-shape gate extraction electrode is provided over the actual operation region. In other words, the grid-shape gate extraction electrode is so provided as to cover the gate electrode and the substrate surface adjacent to the gate electrode. Since a cross-sectional area which can be used as the gate electrode is increased, the gate resistance Rg is reduced.

The inventor of the present application has recognized the following points. As described above, reduction in the ON-resistance Ron has been greatly promoted due to the size reduction. In these years, however, demand for the power MOSFET is not limited to the reduction in the ON-resistance Ron but is diversified. For example, in a case of the power MOSFET for use in a high-speed switch, there is demand not only for the reduction in the ON-resistance Ron and the gate resistance Rg but also for reduction in a parameter “Qgd/Qg” that contributes to a through-current. This is important for realizing the best efficiency in each application. However, when an element is merely miniaturized in order to reduce the ON-resistance Ron, the gate resistance Rg and the gate-to-drain charge Qgd are disadvantageously increased and thus the above-mentioned demand is not satisfied.

According to the technique described in Patent Document 3, the gate resistance Rg is reduced since the grid-shape gate extraction electrode is provided. At the same time, however, the gate charge Qg is increased accordingly. Although the parameter Qgd/Qg is reduced if the gate charge Qg is increased, an excessive increase in the gate charge Qg is not necessarily preferable. For example, let us consider a loss index SW expressed by the following equation.

SW=Qg+Ron+Qgd/Qg×Rg×Vds+Qgd×Rg

(Unit: Qg [nC], Qgd [nC], Ron [mΩ], Rg [Ω], Vds [V])

As is obvious from the above equation, the loss index SW has the parameter Qg independently. Therefore, an unnecessary increase in the gate charge Qg leads to an increase in the loss index SW, which is not preferable.

In order to satisfy the diversified demands, a technique capable of freely designing characteristic parameters of a vertical-type field-effect transistor depending on its intended use is desired.

### SUMMARY

In one embodiment of the present invention, a vertical-type field-effect transistor is provided. The vertical-type field-effect transistor includes: a semiconductor layer having a plurality of trenches formed in a stripe shape; a gate electrode partially embedded in the plurality of trenches; and a base region and a source region that are formed in the semiconductor layer between adjacent trenches among the plurality of trenches. The gate electrode includes: a plurality of first gate structures respectively formed in the plurality of trenches, wherein each of the plurality of first gate structures has a protruding portion protruding from the corresponding trench and an embedded portion embedded in the corresponding trench; and at least one second gate structure formed to connect between the protruding portion of adjacent first gate structures among the plurality of first gate structures. The embedded portion is formed on a side wall of the corresponding trench through a first insulating film. The second gate structure is formed on the source region through a second insulating film thicker than the first insulating film.

In another embodiment of the present invention, a method of manufacturing a vertical-type field-effect transistor is provided. The method includes: (A) forming a plurality of trenches having a stripe shape in a semiconductor layer; (B) forming a base region and a source region in the semiconductor layer between adjacent trenches among the plurality of trenches; (C) performing a thermal oxidation treatment after the (B) process to form a first insulating film on a side wall of the trench and a second insulating film on the source region; (D) blanket depositing a gate material film after the (C) process; and (E) patterning said gate material film to form a gate electrode that is partially embedded in the plurality of trenches. The gate electrode includes: a plurality of first gate structures respectively formed in the plurality of trenches and each of which has a protruding portion that protrudes from the corresponding trench; and at least one second gate structure so formed on the second insulating film as to connect between the protruding portion of adjacent first gate structures among the plurality of first gate structures.

According to the present invention, the gate electrode includes the first gate structure formed in the trench and the second gate structure connecting between any adjacent first gate structures. By forming such the second gate structure, it is possible to reduce the gate resistance Rg and to increase the gate charge Qg. When the gate charge Qg is increased, the parameter “Qgd/Qg” that contributes to the through-current is decreased. These tendencies all contribute to improvement in an efficiency of a power MOSFET. Furthermore, the second gate structure is formed on the source region through the thick second insulating film. Therefore, an excessive increase in the gate charge Qg can be prevented, even when many second gate structures are provided in order to greatly reduce the gate resistance Rg. Moreover, the first gate structure and the second gate structure are collectively formed by patterning a gate material film. Here, a formation pattern of the second gate structure can be designed case by case depending on an intended use (application) of the device. In other words, it is possible to freely design characteristic parameters of the vertical-type field-effect transistor without developing a new manufacturing process with respect to each intended use.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view showing a structure of a vertical-type MOSFET according to an embodiment of the present invention;

FIG. 2A is a cross-sectional view showing a structure taken along a line A-A′ in FIG. 1;

FIG. 2B is a cross-sectional view showing a structure taken along a line B-B′ in FIG. 1;

FIG. 3A is a plan view showing an example of arrangement of bridge gates;

FIG. 3B is a plan view showing another example of arrangement of bridge gates;

FIG. 3C is a plan view showing still another example of arrangement of bridge gates;

FIG. 3D is a plan view showing still another example of arrangement of bridge gates;

FIGS. 4 to 12 are cross-sectional views in a manufacturing process of the vertical-type MOSFET according to the embodiment of the present invention;

FIG. 13A is a cross-sectional view taken along the line A-A′ in the manufacturing process;

FIG. 13B is a cross-sectional view taken along the line B-B′ in the manufacturing process;

FIGS. 14 to 18 are cross-sectional views taken along the line A-A′ in the manufacturing process;

FIGS. 19 to 21 are cross-sectional views in the manufacturing process;

FIG. 22 is a graph showing dependence of a gate-to-drain charge Qgd on a trench depth TD;

FIG. 23 is a table showing various examples of design values of characteristic parameters in the present embodiment;

FIG. 24 is a graph showing a correspondence relationship between a gate resistance Rg and a gate charge Qg; and

FIG. 25 is a graph showing a correspondence relationship between a loss index SW and the gate charge Qg.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

1. Structure

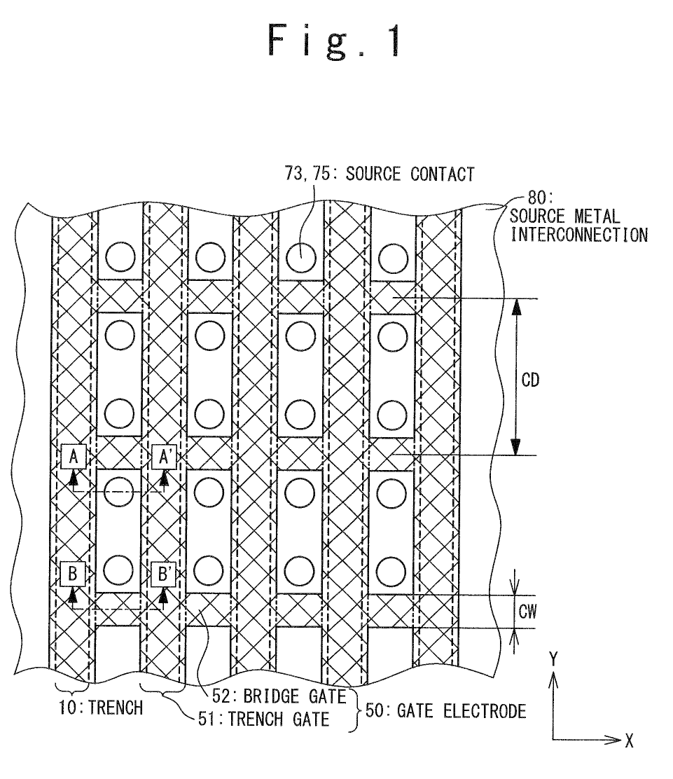

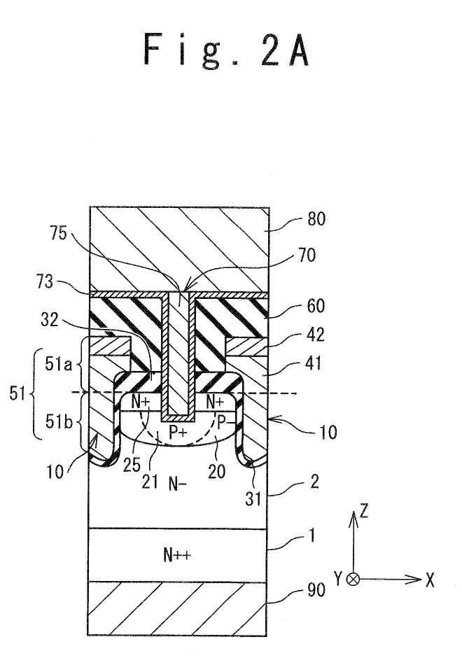

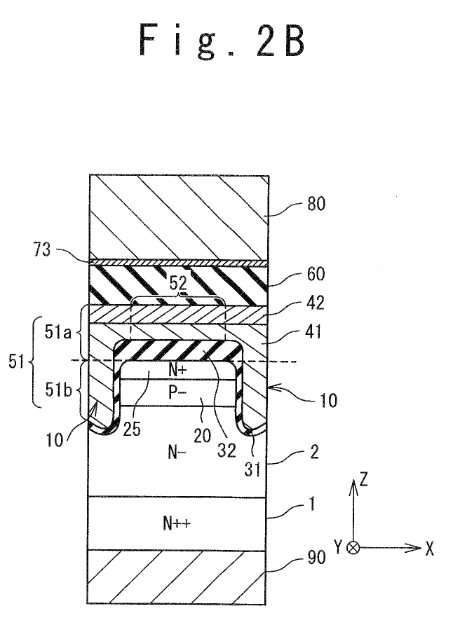

A vertical-type MOSFET will be described below as an example of a vertical-type field-effect transistor. FIG. 1 is a plan view showing a structure of the vertical-type MOSFET according to an embodiment of the present invention. FIGS. 2A and 2B show cross-sectional structures taken along a line A-A′ and a line B-B′ in FIG. 1, respectively. Referring to FIGS. 1, 2A and 2B, the structure of the vertical-type MOSFET′ according to the present embodiment will be described.

As shown in FIGS. 2A and 2B, an N− type epitaxial layer (semiconductor layer) 2 is formed on an N++ type semiconductor substrate 1. The semiconductor substrate 1 is, for example, a silicon substrate. In the present embodiment, the semiconductor substrate 1 and the epitaxial layer 2 formed thereon are used as a substrate.

This substrate has a plurality of trenches 10. More specifically, the plurality of trenches 10 are formed in the epitaxial layer 2. As shown in FIG. 1, the plurality of trenches 10 are formed substantially parallel to each other along a Y-direction. That is, the plurality of trenches 10 are formed in a stripe shape. Note that, in this specification, a horizontal direction orthogonal to the extending direction of the trenches 10 (Y-direction) is defined as an X-direction, and a vertical direction orthogonal to the X-direction and the Y-direction is defined as a Z-direction.

An N+ type source region 25 and a P-type base region are formed in the epitaxial layer 2 between adjacent trenches 10 among the plurality of trenches 10. As shown in FIG. 2A, the P-type base region includes a P− base region 20 and a P+ base region 21. The P+ base region 21 serves as a base contact layer. The N+ type source region 25 is formed at a surface of the epitaxial layer 2.

As shown in FIGS. 2A and 2B, a gate oxide film 31 (first insulating film) is formed on a side wall of each trench 10. Furthermore, a protective oxide film 32 (second insulating film) is formed on the N+ type source region 25. As a result of a manufacturing process described later, the protective oxide film 32 becomes thicker than the gate oxide film 31.

A polysilicon film 41 is formed on the gate oxide film 31 and the protective oxide film 32. Furthermore, a refractory metal film 42 is formed on the polysilicon film 41. The refractory metal film 42 is a metal film whose melting point is higher than 1000 degrees centigrade, for example, a tungsten silicide (WSi) film. The polysilicon film 41 and the refractory metal film 42 are gate material films. By patterning the gate material films, a gate electrode 50 partially embedded in the plurality of trenches 10 is formed. The gate electrode 50 according to the present embodiment has some features and details thereof will be described later.

An interlayer insulating film 60 is so formed as to cover the above-mentioned source region 25 and gate electrode 50. More specifically, as shown in FIGS. 2A and 2B, the interlayer insulating film 60 is formed on the protective oxide film 32 on the source region 25 and the refractory metal film 42. An upper surface of the interlayer insulating film 60 is planarized.

As shown in FIG. 2A, a contact hole 70 is so formed as to penetrate the interlayer insulating film 60, the protective oxide film 32, the source region 25 and a part of the P+ base region 21. A barrier metal film 73 is formed on an inner wall of the contact hole 70 and the surface of the interlayer insulating film 60. The barrier metal film 73 is, for example, a titanium nitride (TiN) film. Furthermore, a contact plug 75 is so formed as to fill the contact hole 70. The contact plug 75 is, for example, a tungsten (W) film. The barrier metal film 73 and the contact plug 75 serve as a source contact (backgate contact). That is, the source contact (73, 75) is so formed as to penetrate the interlayer insulating film 60, the protective oxide film 32 and the source region 25 to reach the P+ base region 21.

Furthermore, a source metal interconnection 80 electrically connected to the above-mentioned source contact (73, 75) is formed. The source metal interconnection 80 is formed on the whole surface of the planarized interlayer insulating film 60. Moreover, a drain metal interconnection 90 (back surface metal interconnection) is formed on a back surface of the N++ type semiconductor substrate 1.

In the present embodiment, the gate electrode 50 is partially embedded in the trenches 10. In other words, a part of the gate electrode 50 is embedded in the plurality of trenches 10. The gate electrode 50 according to the present embodiment includes a plurality of first gate structures 51 and at least one second gate structure 52.

The first gate structure 51 of the gate electrode 50 is a section that is formed along the trench 10 and partially embedded in the trench 10. In this sense, the first gate structure 51 is hereinafter referred to as a “trench gate 51”. As shown in FIG. 1, a plurality of trench gates 51 are respectively formed in the plurality of trenches 10 having the stripe shape. That is to say, the plurality of trench gates 51 are formed substantially parallel to each other along the Y-direction.

Moreover, as shown in FIG. 2A, each trench gate 51 has a “protruding portion 51a” that protrudes from the corresponding trench 10 and an “embedded portion 51b” that is completely embedded in the corresponding trench 10. The embedded portion 51b is located below the protruding portion 51a and formed on the side wall of the trench 10 through the gate oxide film 31 (first insulating film). On the other hand, the protruding portion 51a is located above the embedded portion 51b and partially overlaps the protective oxide film 32 on the source region 25. That is, a width of the protruding portion 51a along the X-direction is larger than a width of the trench 10 along the X-direction. This contributes to reduction in the gate resistance Rg of the gate electrode 50.

The second gate structure 52 of the gate electrode 50 is a section which connects between adjacent trench gates 51 among the plurality of trench gates 51. In this sense, the second gate structure 52 is hereinafter referred to a “bridge gate 52”. In FIG. 1, a plurality of bridge gates 52 are respectively formed to connect between adjacent trench gates 51. The extending direction of each bridge gate 52 is the X-direction orthogonal to the Y-direction.

Specifically, as shown in FIG. 2B, the bridge gate 52 is so formed as to connect between the protruding portions 51a of adjacent trench gates 51. That is, the bridge gate 52 and the protruding portions 51a of the trench gates 51 are formed in the same layer. In other words, the bridge gate 52 is formed on the thick protective oxide film 32 on the source region 25 and below the source metal interconnection 80 through the interlayer insulating film 60. Since the bridge gate 52 connecting between the adjacent trench gates 51 is formed in a different layer from the source metal interconnection 80, the source metal interconnection 80 is not divided by the bridge gate 52, which is preferable from a viewpoint of reduction in the ON-resistance Ron. Moreover, since the thick protective oxide film 32 is interposed between the bridge gate 52 and the source region 25, a gate coupling capacitance is reduced and thus an extreme increase in the gate charge Qg is prevented.

As described later, the bridge gate 52 connecting between the protruding portions 51a of the adjacent trench gates 51 can be formed in the same manufacturing process as the trench gates 51. In other words, by forming a resist mask (not shown) by one photolithography process and patterning a gate material film (41, 42) by using the resist mask, it is possible to collectively form the trench gates 51 and the bridge gate 52. As a result, the plurality of trench gates 51 and the bridge gates 52 are integrally made of the same material. In the example shown in FIG. 2B, the integrally-structured trench gate 51 and bridge gate 52 both are made of the same gate material films (the polysilicon film 41 and the refractory metal film 42). Note that the gate material film includes the refractory metal film 42, which also contributes to reduction in the gate resistance Rg of the gate electrode 50.

As described above, the gate electrode 50 of the vertical-type MOSFET according to the present embodiment has not only the trench gate 51 formed along the trench 10 but also the bridge gates 52 connecting adjacent trench gates 51 to each other. Since the bridge gate 52 is formed, the gate resistance Rg of the gate electrode 50 is reduced and also the gate charge Qg thereof is increased. When the gate charge Qg is increased, the parameter “Qgd/Qg” that contributes to the through-current is decreased. These tendencies all contribute to improvement in an efficiency of the power MOSFET.

Furthermore, the trench gate 51 and the bridge gates 52 can be collectively formed by patterning the gate material film (41, 42). Here, a shape and an area of the bridge gate 52 are arbitrary. That is, a formation pattern of the bridge gate 52 in the gate process can be designed case by case depending on an intended use (application) of the vertical-type MOSFET. In FIG. 1, for example, the plurality of bridge gates 52 are formed, a pitch (distance) between adjacent bridge gates 52 is “CD”, and a width of each bridge gate 52 in the Y-direction is “CW”. The pitch CD and the width CW can be freely designed depending on desired characteristics.

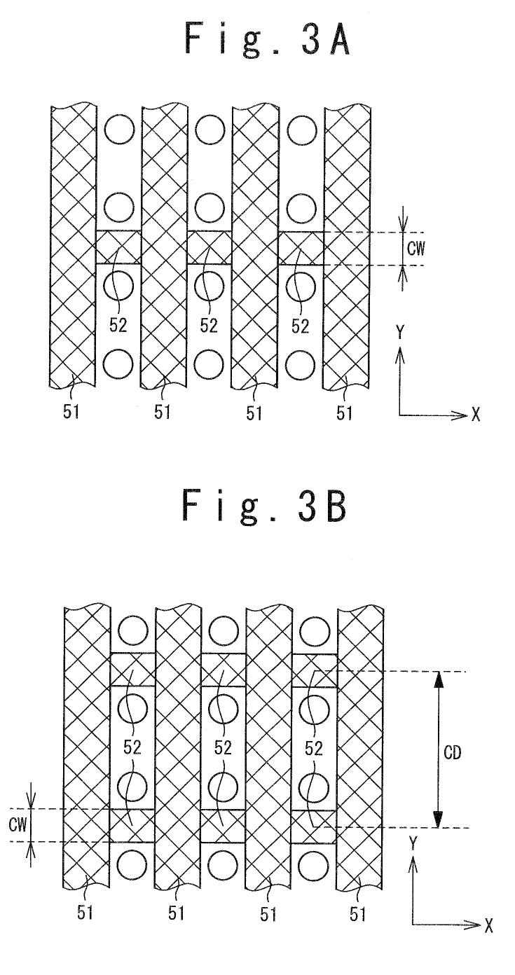

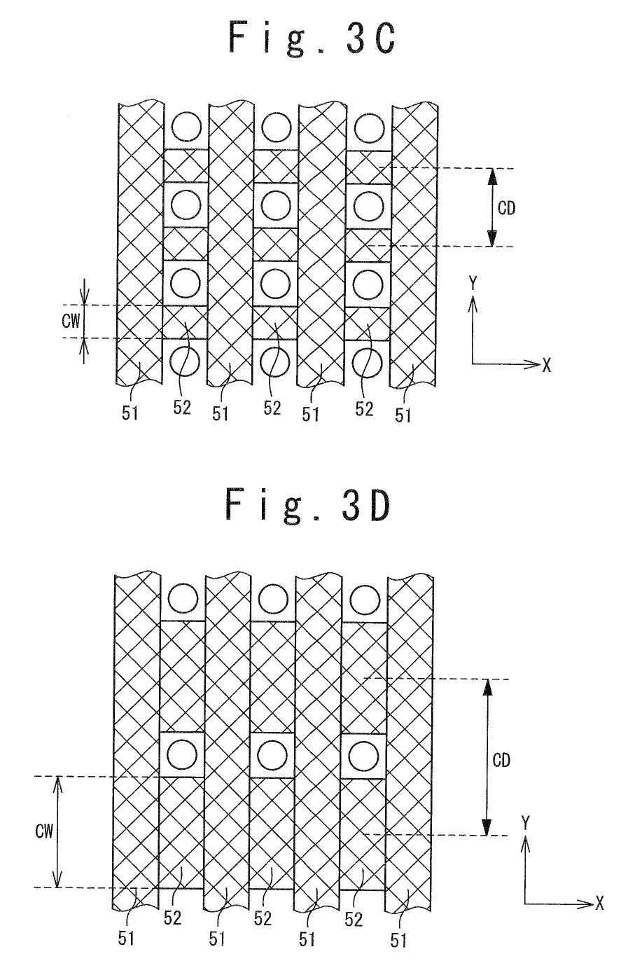

FIGS. 3A to 3D show various formation patterns of the bridge gate 52. As shown in FIGS. 3A to 3D, the pitch CD and the width CW of the bridge gate 52 can be freely designed depending on the desired characteristics. Any pattern can be realized by the patterning during the gate process without affecting the other processes. By merely changing the pattern, namely, by merely changing a mask used in the photolithography process, it is possible to optimize the gate resistance Rg and the gate charge Qg without changing the parameters such as the ON-resistance Ron and the gate-to-drain charge Qgd.

As described above, the bridge gate 52 according to the present embodiment contributes to the reduction in the gate resistance Rg and the increase in the gate charge Qg. The area and pattern of the bridge gate 52 can be freely designed. It is therefore possible to obtain the desired gate resistance Rg and gate charge Qg by freely designing the bridge gates 52. In this sense, the bridge gate 52 in the present embodiment may be also called a “Qg/Rg control gate”. By using the Qg/Rg control gate, it is possible to optimize the gate resistance Rg and the gate charge Qg depending on the intended use of the device. It is not necessary to spend enormous research and development cost for developing a new manufacturing process with respect to each intended use of the device. According to the present embodiment, it is possible to freely design characteristic parameters of the vertical-type MOSFET without developing any new manufacturing process with respect to each intended use.

It should be noted in the present embodiment that a channel is formed along all the trenches irrespective of the pattern of the gate electrode 50. Even when the area of the gate electrode 50 is designed to be large for reducing the gate resistance Rg, the channel region needs not be sacrificed. Thus, both of reduction in the gate resistance Rg and reduction in the ON-resistance Ron can be achieved. Furthermore, it is not necessary to divide the source metal interconnection 80 in the upper layer, whatever pattern the gate electrode 50 has. By blanket forming the source metal interconnection 80 on the entire surface, the ON-resistance Ron can be reduced further.

2. Manufacturing Method

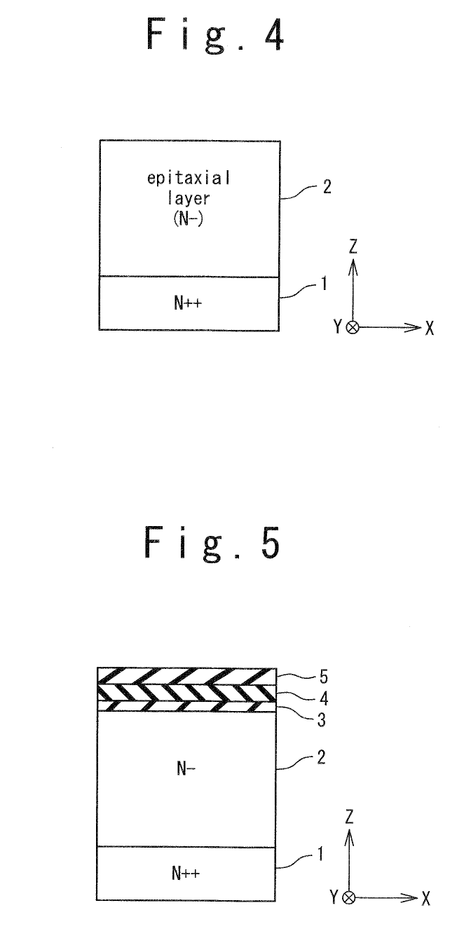

FIGS. 4 to 18 show cross-sectional structures of the vertical-type MOSFET according to the present embodiment in the manufacturing process. Referring to FIGS. 4 to 18, an example of the manufacturing process in the present embodiment will be described.

First, as shown in FIG. 4, the N− type epitaxial layer (semiconductor layer) 2 is formed on the N++ type semiconductor substrate 1 by an epitaxial growth. The semiconductor substrate 1 is, for example, a silicon substrate. Hereinafter, the semiconductor substrate 1 and the epitaxial layer 2 formed thereon are used as a substrate.

Next, a thermal oxidation treatment is performed, and as shown in FIG. 5, an oxide film 3 is formed on the epitaxial layer 2. Further, a nitride film 4 and an oxide film 5 are formed by a CVD (Chemical Vapor Deposition) method.

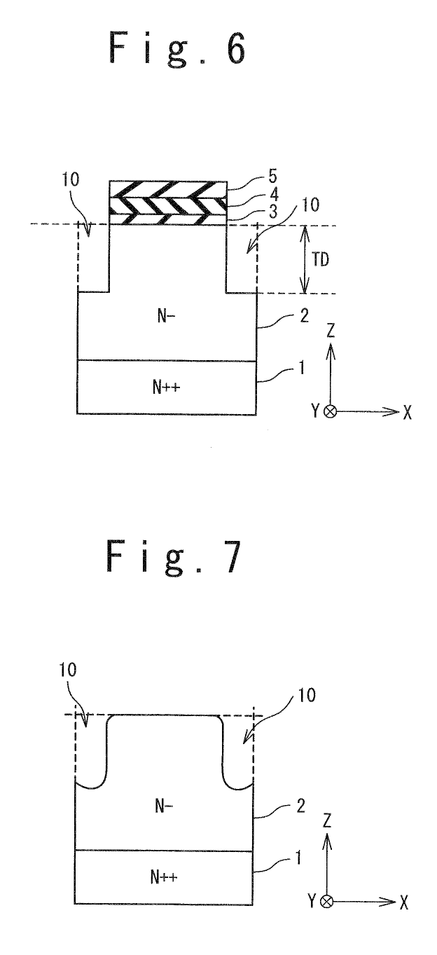

Next, patterning of the oxide film 3, the nitride film 4 and the oxide film 5 is performed by using a resist mask (not shown), and as shown in FIG. 6, a mask used for forming the trenches 10 is formed. Subsequently, an etching (silicon etching) is performed by using the mask and hence the plurality of trenches 10 are formed in the epitaxial layer 2. The plurality of trenches 10 are formed in a stripe shape along the Y-direction. At this time, a depth TD (hereinafter, also referred to a “trench depth TD”) from a surface of the substrate (epitaxial layer 2) to a bottom surface of the trench 10 can be freely designed. As described later, the gate-to-drain charge Qgd can be optimized by controlling the trench depth TD. Note that the trench depth TD can be changed by merely changing a time of the silicon etching.

Next, a high-temperature thermal oxidation treatment is performed. As a result, edges (corner portions) of an opening and a bottom of the trench 10 are rounded. For example, after a sacrificial oxide film is formed on the silicon surface under conditions of oxygen atmosphere and temperature of about 1100 degrees centigrade, the sacrificial oxide film is removed by an etching. When the mask film is completely removed, a structure shown in FIG. 7 can be obtained. As shown in FIG. 7, the corner portions of the opening and the bottom of each trench 10 are all rounded.

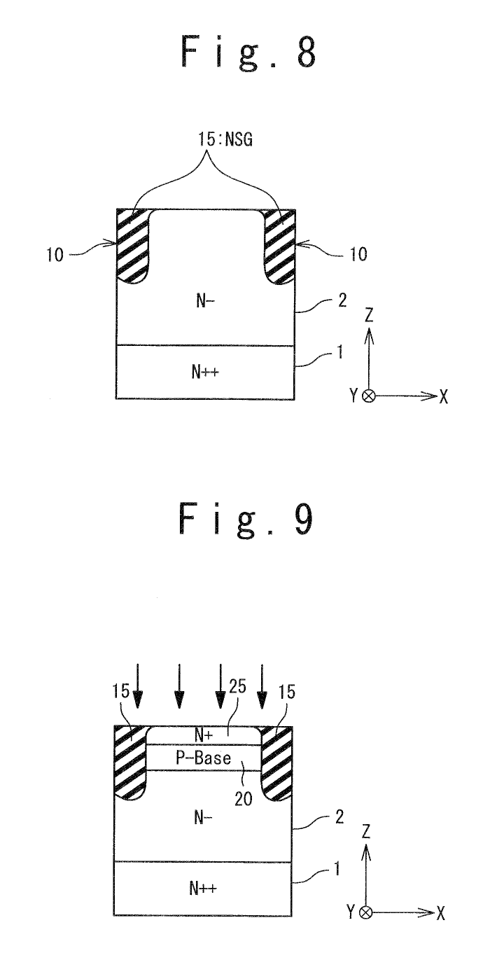

Next, an NSG (Non-doped Silicate Glass) film 15 is blanket deposited by the CVD method, and then an etch-back is performed. As a result, as shown in FIG. 8, NSG films 15 (embedded insulating film) which fill the plurality of trenches 10 are formed.

Next, an ion implantation is performed, and as shown in FIG. 9, the P− type base region 20 and the N+ type source region 25 are formed in a self-aligned manner. More specifically, a boron (B) ion implantation is performed and the P− base region 20 is formed in the epitaxial layer 2 between adjacent trenches 10. Moreover, an arsenic (As) ion implantation is performed and the N+ type source region 25 is formed at the surface of the epitaxial layer 2 between adjacent trenches 10. In this manner, a channel region of the vertical-type MOSFET is formed.

Next, a plasma etching of the NSG film 15 is performed. At this time, as shown in FIG. 10, the NSG film 15 is left at least on a side wall of the trench 10. After that, the NSG film 15 left on the side wall is removed by a wet etching. As a result of this process, the side wall of the trench 10 can be prevented from being damaged by the plasma etching.

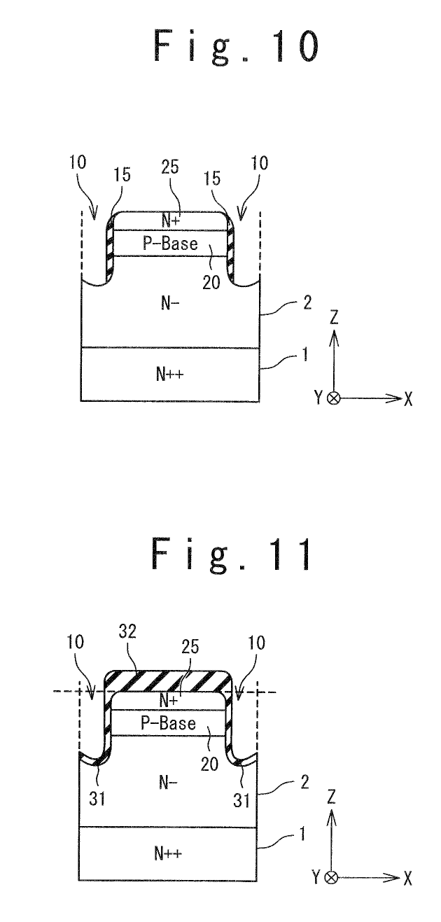

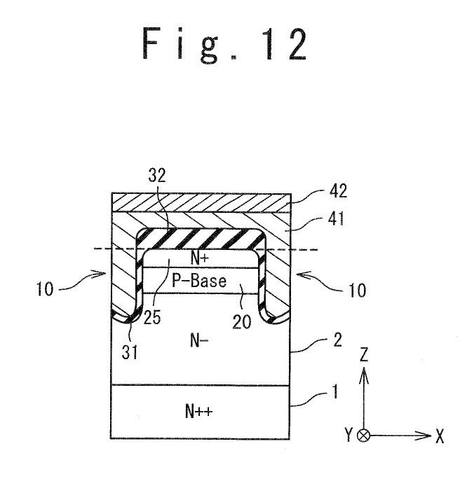

Next, a thermal oxidation treatment is performed, and as shown in FIG. 11, the gate oxide film 31 (first insulating film) is formed on the side wall of the trench 10. A thickness of the gate oxide film 31 is 500 Å, for example. Since the side wall of the trench 10 is prevented from being damaged by the plasma etching as explained above, the gate oxide film 31 of high quality can be formed. As a result, reliability of the device is improved. Moreover, the protective oxide film 32 (second insulating film) is formed on the N+ type source region 25, concurrently with the gate oxide film 31. At this time, the thick protective oxide film 32 is formed, because the oxidation is promoted on the N+ type source region 25. Specifically, the protective oxide film 32 becomes thicker than the gate oxide film 31, and its thickness is 2000 Å for example. The reason why such a thick protective oxide film 32 is formed is that the N+ type source region 25 is formed prior to the gate oxidation. Since the thick protective oxide film 32 is formed on the corner portion of the opening of the trench 10, an effect of improving reliability can be obtained. Furthermore, since the thick protective oxide film 32 is interposed between the source region 25 and the bridge gate 52 to be formed later, an effect of reducing the gate coupling capacitance can also be obtained.

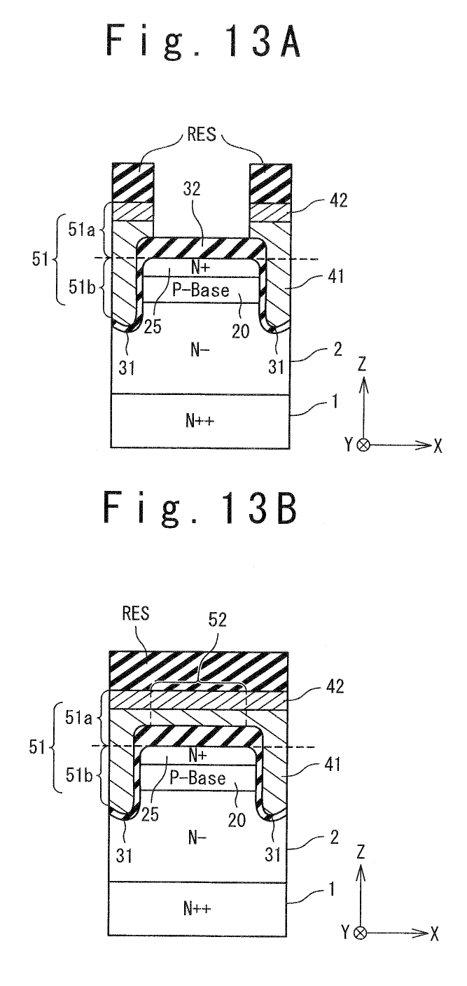

Next, as shown in FIG. 12, the gate material films (41, 42) as a material for the gate electrode are blanket formed. More specifically, the polysilicon film 41 is blanket deposited by the CVD method so as to fill the trenches 10 and cover the protective oxide film 32. Here, a surface of the polysilicon film 41 may be planarized. Further, the refractory metal film 42 is formed on the polysilicon film 41 by a sputtering method. The refractory metal film 42 is a metal film whose melting point is higher than 1000 degrees centigrade, for example, a tungsten silicide (WSi) film. For example, a thickness of the WSi film is one fourth or more of the total film thickness (polysilicon+WSi).

Next, patterning of the gate material films 41 and 42 is performed by using a resist mask RES. As a result, the gate electrode 50 partially embedded in the plurality of trenches 10 is formed. As described above, the gate electrode 50 includes the plurality of trench gates 51 (first gate structures) and at least one bridge gate 52 (second gate structure). Here, the formation pattern of the gate electrode 50 is arbitrary (refer to FIGS. 3A to 3D)

FIG. 13A shows a cross-sectional structure taken along the line A-A′ at this time. FIG. 13B shows a cross-sectional structure taken along the Line B-B′ at this time. As shown in FIGS. 13A and 13B, the resist mask RES is formed on the gate material films 41 and 42. The resist mask RES can be so formed by a lithography as to have a desired pattern of the gate electrode 50. The pattern of the resist mask RES can be designed case by case depending on the intended use of the device (see FIGS. 1, and 3A to 3D). By using the resist mask RES, the etching (patterning) of the gate material films 41 and 42 is performed. By merely changing the mask pattern, the trench gate 51 and the bridge gate 52 which have the desired pattern can be collectively formed.

The trench gate 51 is formed in a stripe shape along the trench 10 and has the protruding portion 51a protruding from the trench 10 and the embedded portion 51b embedded in the trench 10. The embedded portion 51b is formed on the side wall of the trench 10 through the gate oxide film 31. The protruding portion 51a is so formed as to be located above the embedded portion 51b and partially overlaps the protective oxide film 32. In other words, a width of the protruding portion 51a along the X-direction is larger than a width of the trench 10 along the X-direction. This also contributes to the reduction in the gate resistance Rg of the gate electrode 50. On the other hand, as shown in FIG. 13B, the bridge gate 52 is so formed as to connect between the protruding portions 51a of adjacent trench gates 51. This contributes to the reduction in the gate resistance Rg and the increase in the gate charge Qg. Moreover, the bridge gate 52 is formed on the thick protective oxide film 32 on the source region 25. This is preferable from the viewpoint of reduction in the coupling capacitance between the bridge gate 52 and the source region 25.

In this manner, the trench gate 51 and the bridge gate 52 are integrally made of the same material in the gate process. As described above, the bridge gate 52 serves as the Qg/Rg control gate. It is possible to freely design the area and pattern of the bridge gate 52 such that desired gate resistance Rg and gate charge Qg depending on the intended use of the device are obtained. Conversely speaking, the desired gate resistance Rg and gate charge Qg can be obtained by merely changing the area and pattern of the bridge gate 52 depending on the intended use. There is no need to change the processes or develop a new process in order to obtain the desired gate resistance Rg and gate charge Qg corresponding to the intended use.

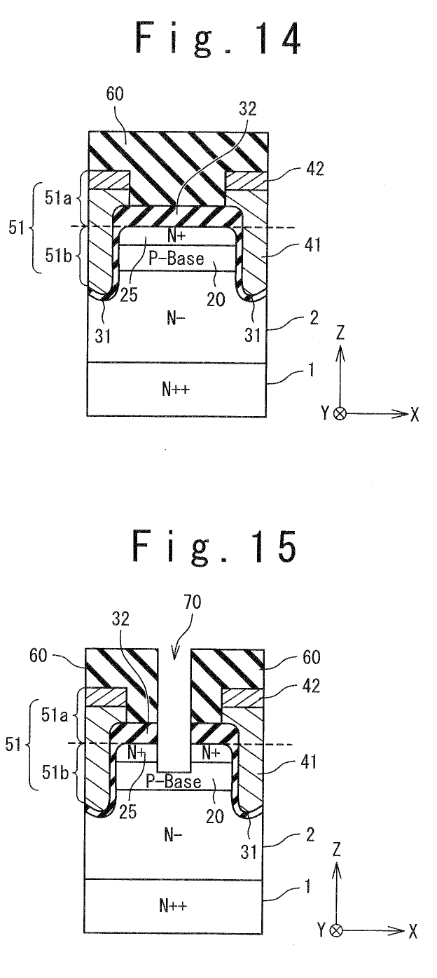

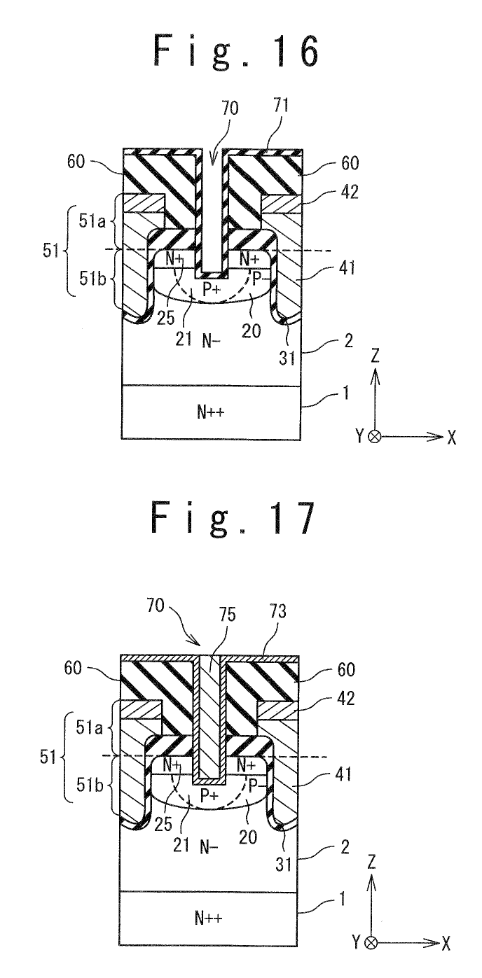

Hereinafter, FIGS. 14 to 18 show cross-sectional structures taken along the line A-A′. Firstly, as shown in FIG. 14, the interlayer insulating film 60 is blanket deposited by the CVD method. An upper surface of the interlayer insulating film 60 is planarized.

Next, as shown in FIG. 15, the contact hole 70 is formed by an etching using a resist mask (not shown). The contact hole 70 is so formed as to penetrate the interlayer insulating film 60, the protective oxide film 32 and the source region 25 to reach the P− base region 20.

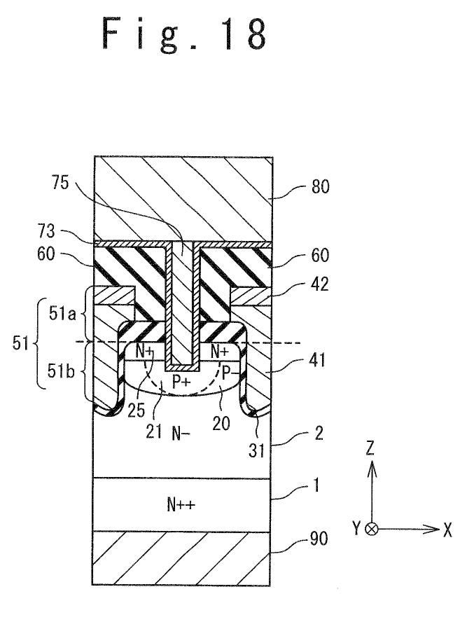

Next, as shown in FIG. 16, a sacrificial oxide film 71 is blanket deposited by the CVD method. Subsequently, a boron (B) ion implantation is performed and an annealing is performed at a temperature of 600 to 1000 degrees centigrade. As a result, the P+ base region 21 is formed in a base region in the vicinity of a bottom surface of the contact hole 70. The P+ base region 21 serves as the base contact layer. After that, the sacrificial oxide film 71 is removed.

Next, as shown in FIG. 17, the barrier metal film 73 is formed on an inner wall of the contact hole 70 and the surface of the interlayer insulating film 60. The barrier metal film 73 is, for example, a titanium nitride (TiN) film formed by the sputtering method. Further, the contact plug 75 is so formed as to fill the contact hole 70. The contact plug 75 is, for example, a tungsten (W) film. The barrier metal film 73 and the contact plug 75 serve as a source contact (backgate contact). In this manner, the source contact (73, 75) which penetrate the interlayer insulating film 60, the protective oxide film 32 and the source region 25 to reach the P+ base region 21 is formed.

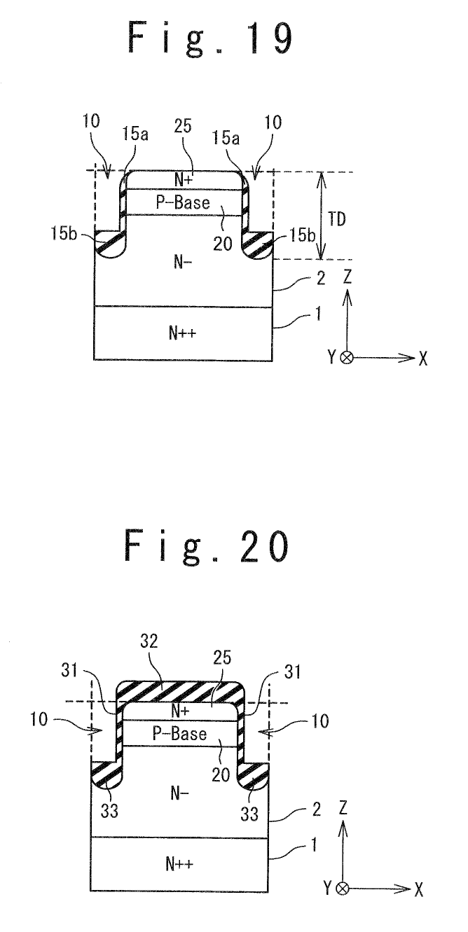

Next, as shown in FIG. 18, the source metal interconnection 80 electrically connected to the above-mentioned source contact (73, 75) is formed. The source metal interconnection 80 is, for example, an aluminum interconnection formed by the sputtering method. The source metal interconnection 80 is formed on the whole surface of the planarized interlayer insulating film 60. Here, it is not necessary to divide the source metal interconnection 80 in the upper layer, whatever pattern the gate electrode 50 in the lower layer has. By blanket forming the source metal interconnection 80 on the entire surface, the ON-resistance Ron can be reduced. Furthermore, the drain metal interconnection 90 (back surface metal interconnection) is formed on a back surface of the N++ type semiconductor substrate 1. Alternatively, the following process is applicable: a drain contact plug (not shown) extending from the interlayer insulating film 60 to the N++ type semiconductor substrate 1 is formed and then connected to the drain metal interconnection 90, thereby simultaneously forming the drain metal interconnection 90 and the source metal interconnection 80.

In this manner, the vertical-type MOSFET according to the present embodiment can be manufactured. The manufacturing method according to the present embodiment can be summarized as follows.

A method of manufacturing a vertical-type field-effect transistor comprises: (A) forming a plurality of trenches having a stripe shape in a semiconductor layer; (B) forming a base region and a source region in the semiconductor layer between adjacent trenches among the plurality of trenches; (C) performing a thermal oxidation treatment after the (B) process to form a first insulating film on a side wall of the trench and a second insulating film on the source region; (D) blanket depositing a gate material film after the (C) process; and (E) patterning said gate material film to form a gate electrode that is partially embedded in the plurality of trenches. The gate electrode comprises: a plurality of first gate structures respectively formed in the plurality of trenches and each of which has a protruding portion that protrudes from the corresponding trench; and at least one second gate structure so formed on the second insulating film as to connect between the protruding portion of adjacent first gate structures among the plurality of first gate structures.

In the above-mentioned (E) process, the gate electrode may be formed such that a width of the protruding portion is larger than a width of the corresponding trench.

The method can further comprise: (a) forming an embedded insulating film in the plurality of trenches after the (A) process and before the (B) process; and (b) removing at least a part of the embedded insulating film after the (B) process and before the (C) process.

In the above-mentioned (b) process, all of the embedded insulating film may be removed. Alternatively, the embedded insulating film may be left at least on a bottom surface of the corresponding trench.

3. Free Design of Trench Depth TD

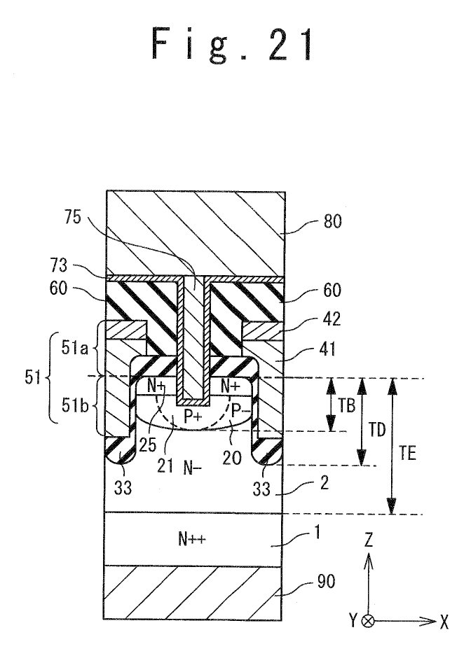

As shown in FIG. 6, the plurality of trenches 10 are formed in the epitaxial layer 2 by the trench etching. The “trench depth TD” in the trench etching can be freely designed without affecting other processes. Referring to FIGS. 19 and 20, the free design of the trench depth TD will be described. FIG. 19 corresponds to the foregoing FIG. 10, and FIG. 20 corresponds to the foregoing FIG. 11.

As shown in FIG. 19, in the plasma etching process for the NSG film 15, the NSG film 15 can be left not only on the side wall of the trench 10 but also on a bottom surface of the trench 10. For example, when the trench depth TD is designed to be relatively large, the NSG film 15a is left on the side wall of the trench 10 and the NSG film 15b is also left on the bottom surface of the trench 10. That is, the plasma etching is performed such that the NSG film 15b on the bottom surface as well as the NSG film 15a on the side wall is left.

The subsequent processes are the same as described above. The NSG film 15a left on the side wall of the trench 10 is removed by the wet etching. As a result, the side wall of the trench 10 can be prevented from being damaged by the plasma etching. Subsequently, the thermal oxidation treatment is performed. As a result, as shown in FIG. 20, the high-quality gate oxide film 31 is formed on the side wall of the trench 10, and the thick protective oxide film 32 is formed on the source region 25. Thus, the reliability is improved. Furthermore, in the case of FIG. 20, a “bottom oxide film 33 (third insulating film)” corresponding to the NSG film 15b is formed on the bottom surface of the trench 10. The bottom oxide film 33 is thicker than the gate oxide film 31.

The only difference between FIG. 20 and the foregoing FIG. 11 is whether or not the bottom oxide film 33 exists on the bottom surface of the trench 10. When the trench depth TD is designed to be relatively large, the bottom oxide film 33 is left on the bottom surface of the trench 10, and the other structures are the same. For example, there is no need to change time for depositing the gate material films (41, 42), and therefore a depth of the gate electrode 50 within the trench 10 is not changed. The gate electrode 50 in the trench 10 is automatically raised by the bottom oxide film 33. In this manner, there is no need to change the other processes even if the trench depth TD is changed. It can be said that this effect is obtained because the NSG film 15 is embedded in the trench 10.

As described above, the trench depth TD can be freely changed without affecting the other processes. This means that a designer can freely design the trench depth TD such that the device characteristics are optimized. Effects obtained by the free design of the trench depth TD will be described below.

FIG. 21 corresponds to the foregoing FIG. 18. As shown in FIG. 21, the trench depth TD is a depth from the surface of the substrate (the epitaxial layer 2) to the bottom surface of the trench 10. Moreover, a depth from the surface of the substrate (the epitaxial layer 2) to a bottom surface of the base region (the P-base region 20 and the P+ base region 21) is defined as a “base region depth TB”. A depth from the surface of the substrate (the epitaxial layer 2) to a bottom surface of the epitaxial layer 2 is defined as an “epilayer depth TE”.

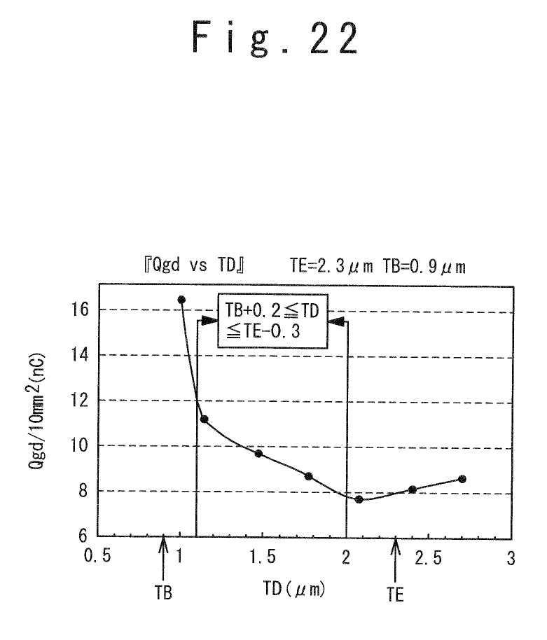

FIG. 22 shows a dependence of the gate-to-drain charge Qgd on the trench depth TD in the structure shown in FIG. 21. A horizontal axis represents the trench depth TD and a vertical axis corresponds to the parameter Qgd. Here, the base region depth TB is 0.9 μm and the epilayer depth TE is 2.3 μm. In order to reduce the “parameter Qgd/Qg” that contributes to the through-current, it is desirable to make the parameter Qgd as small as possible.

As shown in FIG. 22, as the trench depth TD increases from the smaller value, the parameter Qgd tends to decrease. In particular, when the trench depth TD exceeds “TB (=0.9 μm)+0.2 μm”, a sufficiently small parameter Qgd is realized. It is therefore preferable that the trench depth TD is “TB+0.2 μm” or more. On the other hand, when the trench depth TD exceeds “TE (=2.3 μm)−0.3 μm”, the decreasing trend of the parameter Qgd turns into an increasing trend. It is therefore preferable that the trench depth TD is “TE−0.3 μm” or less. In summary, it is preferable that the trench depth TD is designed in a range from “TB+0.2 μm” to “TE−0.3 μm”. Thus, the parameter Qgd can be sufficiently reduced, and thereby the parameter Qgd/Qg can also be sufficiently reduced.

As described above, the parameter Qgd/Qg can be reduced by freely designing the trench depth TD. In order to change the trench depth TD, the time for the trench etching just needs to be changed, and the other processes need not be modified.

4. Consideration

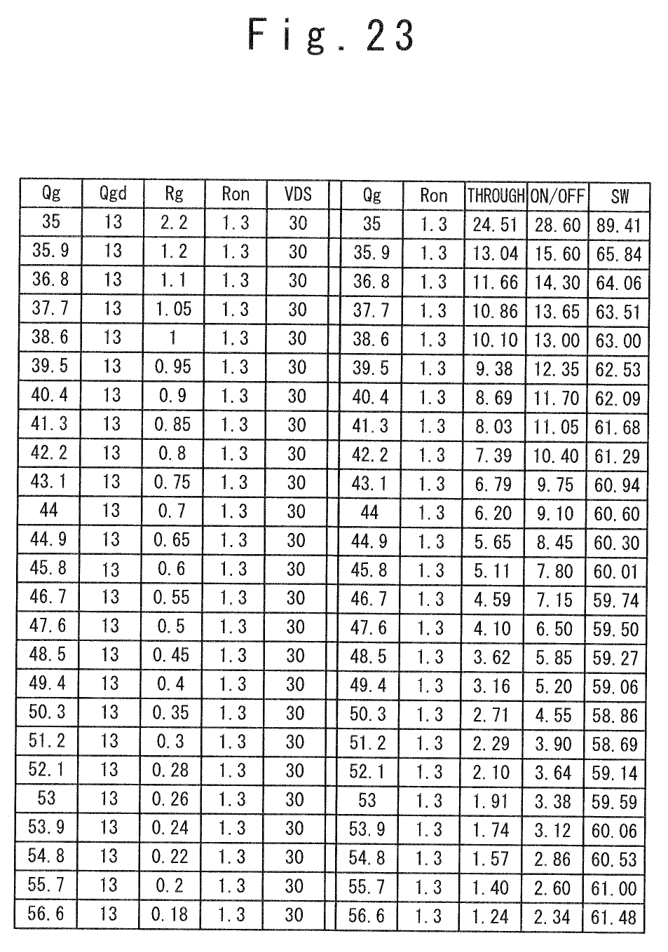

According to the present embodiment, as described above, the characteristic parameters (Rg, Qg, Qgd/Qg, SW and the like) of the vertical-type MOSFET can be freely designed. FIG. 23 is a table showing various design examples of the characteristic parameters of the vertical-type MOS transistor according to the present embodiment. Each design value was acquired as a result of a simulation conducted by the inventor. The vertical-type MOSFET according to the present embodiment will be discussed below with reference to FIG. 23 as appropriate.

(1) Rg, Qg

The gate electrode 50 of the vertical-type MOSFET according to the present embodiment includes the trench gate 51 formed along the trench 10 and the bridge gate 52 connecting between adjacent trench gates 51. The width of the protruding portion 51a of the trench gate 51 is larger than the width of the trench 10. This contributes to the reduction in the gate resistance Rg and the increase in the gate charge Qg. Furthermore, by forming the bridge gate 52 connecting between the trench gates 51, it is possible to reduce the gate resistance Rg and to increase the gate charge Qg.

Moreover, the number, placement location and area of the bridge gate 52 in the present embodiment can be appropriately determined such that the desired gate resistance Rg and gate charge Qg are obtained. In the gate process, the formation pattern of the bridge gate 52 can be designed case by case depending on the intended use of the device. Any pattern can be realized by the patterning during the gate process without affecting the other processes. By merely changing the pattern, it is possible to optimize the gate resistance Rg and the gate charge Qg without changing the parameters such as the ON-resistance Ron and the gate-to-drain charge Qgd.

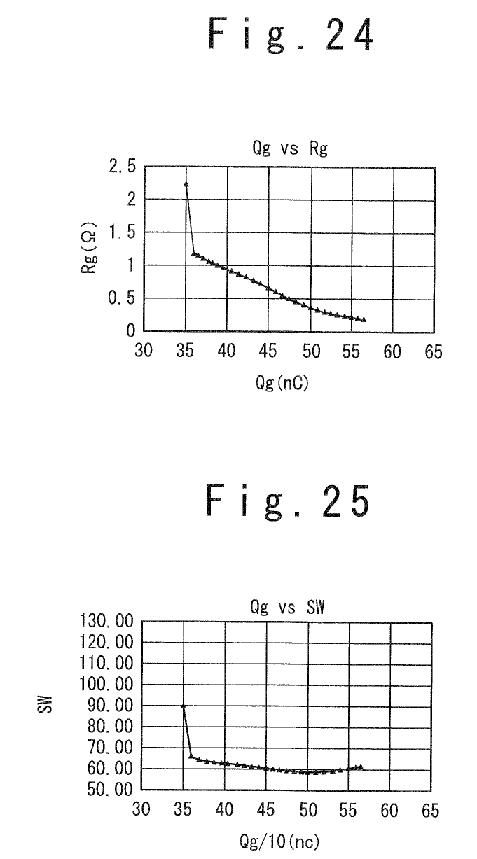

FIG. 24 is a graph showing a correspondence relationship between the gate resistance Rg and the gate charge Qg. As can be clearly seen from FIGS. 23 and 24, the gate resistance Rg can be reduced according to the present embodiment. As the gate resistance Rg becomes smaller, the gate charge Qg is increased. When the gate charge Qg is increased, the parameter “Qgd/Qg” is decreased and thus the through-current is reduced. These tendencies all contribute to improvement in the efficiency of a power MOSFET.

As a comparative example, let us consider the technique described in the above-mentioned Patent Document 1. According to the technique, the number of gate metal interconnections formed above a gate electrode may be increased in order to reduce the gate resistance Rg. In this case, however, the gate charge Qg does not change even if the gate resistance Rg is reduced. Therefore, the effects according to the present embodiment cannot be obtained. Moreover, in the case of Patent Document 1, when the number of gate metal interconnections is increased, need for dividing a source metal interconnection is increased accordingly. When the source metal interconnection is divided, its resistance is increased and thus the ON-resistance Ron as a whole chip is disadvantageously increased.

As described above, the bridge gate 52 according to the present embodiment contributes to the reduction in the gate resistance Rg and the increase in the gate charge Qg. The area and pattern of the bridge gate 52 can be freely designed. That is to say, desired gate resistance Rg and gate charge Qg can be obtained by freely designing the bridge gate 52. It is possible to optimize the gate resistance Rg and the gate charge Qg depending on the intended use of the device. It is not necessary to spend enormous research and development cost for developing a new manufacturing process with respect to each intended use of the device.

(2) Qgd

As described in the foregoing Section 3, according to the present embodiment, the trench depth TD can be freely designed without affecting the other processes. In other words, it is possible to design the trench depth TD such that desired device characteristics are obtained, without changing the processes. In particular, it is preferable that the trench depth TD is set in the range from “TB+0.2 μm” to “TE−0.3 μm”. Thus, the parameter Qgd can be sufficiently reduced, and thereby the parameter Qgd/Qg can also be sufficiently reduced. It can be said that the parameter Qgd/Qg contributing to the through-current can be set variably even in the same process.

(3) Ron

According to the present embodiment, a channel is formed along all the trenches 10 irrespective of the pattern of the gate electrode 50. Even when the area of the gate electrode 50 is designed to be large for reducing the gate resistance Rg, the channel region needs not be sacrificed. Thus, both of reduction in the gate resistance Rg and reduction in the ON-resistance Ron can be achieved.

Furthermore, it is not necessary to divide the source metal interconnection 80 in the upper layer, whatever pattern the gate electrode 50 has. Since the bridge gate 52 connecting between the trench gates 51 is formed in a different layer from the source metal interconnection 80, the source metal interconnection 80 is not divided by the bridge gate 52. It is therefore possible to blanket form the source metal interconnection 80 on the entire surface, which enables further reduction in the ON-resistance Ron.

(4) Loss Index SW

In the present embodiment, the loss index SW is expressed as the following equation.

SW=Qg+Ron+Qgd/Qg×Rg×Vds+Qgd×Rg

(unit: Qg [nC], Qgd [nC], Ron [mΩ], Rg [Ω], Vds [V])

According to the present embodiment, the characteristic parameters such as Qg, Rg, Qgd and Qgd/Qg can be designed freely and independently from each other. It is therefore possible to optimize the respective characteristic parameters such that the loss index SW becomes small. It should be noted in the above equation that the loss index SW has the parameter Qg independently. An extreme increase in the gate charge Qg causes an increase in the loss index SW, which is riot preferable. According to the technique described in the above-mentioned Patent Document 3, since a gate oxide film is formed by thermal oxidation and a gate extraction electrode connecting between trench gate electrodes is formed before a source region is formed, only the thin gate oxide film exists below the gate extraction electrode, which may result in an excessive increase in the gate charge Qg. According to the present embodiment, as described above, the bridge gate 52 is formed on the source region 25 through the thick protective oxide film 32. Therefore, an excessive increase in the gate charge Qg can be prevented, even when many bridge gates 52 are provided in order to greatly reduce the gate resistance Rg.

FIG. 25 is a graph showing a correspondence relationship between the loss index SW and the gate charge Qg. As shown in FIGS. 23 and 25, according to the present embodiment, the respective parameters can be optimized such that the loss index SW becomes small. Even if the gate charge Qg becomes large due to the reduction in the gate resistance Rg, the loss index SW can be kept at a low level. In this manner, the respective characteristic parameters can be optimized so that the device can provide the best efficiency in a used application.

(5) High-Quality Oxide Film

As described above, prior to the gate oxidation process, the NSG film 15 is so formed as to fill the trenches 10 (see FIG. 8) and the P− base region 20 and the source region 25 are formed in a self-aligned manner (see FIG. 9). Furthermore, after the plasma etching is performed such that the NSG film 15 is left at least on the side wall of the trench 10, the NSG film 15 left on the side walls is removed by the wet etching (see FIG. 10). As a result, the side wall of the trench 10 can be prevented from being damaged. After that, the gate oxidation process is performed. Consequently, the high-quality gate oxide film 31 is formed on the side wall of the trench 10 and thus the reliability is improved. At the same time, since the N+ type source region 25 is already formed, the thick protective oxide film 32 is formed on the source region 25 by accelerating oxidation (see FIG. 11). Since the thick protective oxide film 32 is formed on the cornered portion of the opening of the trench 10, the reliability is further improved. Furthermore, since the thick protective oxide film 32 is interposed between the source region 25 and the bridge gate 52, the effect that the gate coupling capacitance is reduced can also be obtained. In this manner, the reliability is improved according to the present embodiment, because the high-quality gate oxide film 31 and the thick protective oxide film 32 are formed.

According to the present embodiment, as described above, the respective characteristic parameters can be optimized so that the device can provide the best efficiency in a used application. Moreover, since the high-quality oxide film is produced, the reliability is improved. These fully satisfy all demands for, for example, a power MOSFET for use in a high-speed switch. Furthermore, it is possible to freely design the characteristic parameters without developing any new manufacturing process with respect to each intended use of the device. Since it is not necessary to spend an enormous research and development cost to develop a new process for changing the characteristic parameters, costs are greatly reduced.

It should be noted that the vertical-type MOS transistor and the method of manufacturing thereof according to the present invention are not limited to the above-mentioned embodiment and can be variously modified.

In the above-mentioned embodiment, the second insulating film 32 and the first insulating film 31 are simultaneously formed to avoid an increase in the number of processes. However, the second insulating film 32 and the first insulating film 31 may be formed separately. For example, after the P− base region 20 and the source region 25 are formed as shown in FIG. 9, the following processes may be performed. That is, the second insulating film (protective insulating film) 32 is blanket formed by the CVD method or the like, a mask covering above the source region 20 is formed, and then the second insulating film 32 and the NSG film 15 which are formed on the trench 10 are removed by using the mask. In this case, the gate charge Qg can be optimized according to a dielectric constant and a thickness of the second insulating film. 32 formed by the CVD method or the like.

The bottom oxide film 33 is not necessarily an oxide film. For example, when a silicon oxynitride film (SiON film) having a large dielectric constant is used instead of the oxide film, the gate-to-drain charge Qgd can be further reduced.

A plurality of trenches means that there are stripe-shape trench portions, which includes a case where the structure further has an extension trench at ends of a plurality of trenches and the plurality of trenches are connected with each other by the extension trench to constitute one trench as a whole. An extension gate structure extending from the first gate structure 51 may be formed in the extension trench.

Moreover, as to the conductive type, the N type and the P type may be reversed. Furthermore, although the MOS transistor has been described as an example in the above-mentioned embodiment, the present invention can be applied to various semiconductor devices having a gate electrode embedded in a trench, such as an IGBT (Insulated Gate Bipolar Transistor).

It is apparent that the present invention is riot limited to the above embodiments and may be modified and changed without departing from the scope and spirit of the invention.

What is claimed is:

1. A vertical-type field-effect transistor comprising:
a semiconductor layer having a plurality of trenches formed in a stripe shape;
a gate electrode partially embedded in said plurality of trenches; and
a base region and a source region that are formed in said semiconductor layer between adjacent trenches among said plurality of trenches,
wherein said gate electrode comprises:
a plurality of first gate structures respectively formed in said plurality of trenches, wherein each of said plurality of first gate structures comprises: a protruding portion that protrudes from the corresponding trench; and an embedded portion that is embedded in the corresponding trench; and
at least one second gate structure formed to connect between said protruding portion of adjacent first gate structures among said plurality of first gate structures,
wherein said embedded portion is formed on a side wall of the corresponding trench through a first insulating film, and
said second gate structure is formed on said source region through a second insulating film thicker than said first insulating film.

2. The vertical-type field-effect transistor according to claim 1,
wherein said plurality of first gate structures and said at least one second gate structure are integrally made of a same material.

3. The vertical-type field-effect transistor according to claim 1,
wherein a width of said protruding portion is larger than a width of the corresponding trench.

4. The vertical-type field-effect transistor according to claim 1,
wherein a third insulating film thicker than said first insulating film is formed between a bottom surface of said embedded portion and a bottom surface of the corresponding trench.

5. The vertical-type field-effect transistor according to claim 4,
wherein said semiconductor layer is an epitaxial layer,
a depth from a surface of said epitaxial layer to said bottom surface of the corresponding trench is TD,
a depth from said surface of said epitaxial layer to a bottom surface of said base region is TB,
a depth from said surface of said epitaxial layer to a bottom surface of said epitaxial layer is Te, and
TD is in a range from TB+0.2 μm to TE−0.3 μm.

6. A method of manufacturing a vertical-type field-effect transistor comprising:
forming a plurality of trenches having a stripe shape in a semiconductor layer;
forming a base region and a source region in said semiconductor layer between adjacent trenches among said plurality of trenches;
performing a thermal oxidation treatment after forming said base region and said source region, to form a first insulating film on a side wall of each of said plurality of trenches and a second insulating film on said source region;
blanket depositing a gate material film after said thermal oxidation treatment; and
patterning said gate material film to form a gate electrode that is partially embedded in said plurality of trenches,
wherein said gate electrode comprises:
a plurality of first gate structures respectively formed in said plurality of trenches and each of which has a protruding portion that protrudes from the corresponding trench; and
at least one second gate structure so formed on said second insulating film as to connect between said protruding portion of adjacent first gate structures among said plurality of first gate structures.

7. The method according to claim 6,
wherein said gate electrode is formed such that a width of said protruding portion is larger than a width of the corresponding trench.

8. The method according to claim 6 further comprising:
forming an embedded insulating film in each of said plurality of trenches after forming said plurality of trenches and before forming said base region and said source region; and
removing at least a part of said embedded insulating film after forming said base region and said source region and before said thermal oxidation treatment.

9. The method according to claim 8,
wherein in said removing, all of said embedded insulating film is removed.

10. The method according to claim 8,
wherein in said removing, said embedded insulating film is left at least on a bottom surface of said each trench.

11. The method according to claim 10,
wherein said semiconductor layer is an epitaxial layer,
a depth from a surface of said epitaxial layer to a bottom surface of said each trench is TD,
a depth from said surface of said epitaxial layer to a bottom surface of said base region is TB, and
a depth from said surface of said epitaxial layer to a bottom surface of said epitaxial layer is Te,
wherein in said forming said plurality of trenches, TD is set in a range from TB+0.2 μm to TE−0.3 μm.
